(19) United States
(12) Patent Application Publication
(10) Pub. No.: US 2018/0130707 A1
(43) Pub. Date: May 10, 2018

(54) BOTTOM-UP FILL (BUF) OF METAL FEATURES FOR SEMICONDUCTOR STRUCTURES

(71) Applicant: Intel Corporation, Santa Clara, CA (US)

(72) Inventors: Scott B. CLENDENNING, Portland, OR (US); Martin M. MITAN, Hillsboro, OR (US); Timothy E. GLASSMAN, Portland, OR (US); Flavio GRIGGIO, Portland, OR (US); Grant M. KLOSTER, Lake Oswego, OR (US); Kent N. FRASURE, Hillsboro, OR (US); Florian GSTREIN, Portland, OR (US); Rami HOURANI, Portland, OR (US)

(21) Appl. No.: 15/573,108

(22) PCT Filed: Jun. 18, 2015
(86) PCT No.: PCT/US2015/036519

§ 371 Date: Nov. 9, 2017

(51) Int. Cl. H01L 21/768; H01L 21/285; H01L 21/311

(52) U.S. Cl. CPC H01L 21/76879; H01L 21/76876; H01L 21/28562; H01L 2221/1063; H01L 21/76865; H01L 21/31144; H01L 21/76843

(57) ABSTRACT

Bottom-up fill approaches for forming metal features of semiconductor structures, and the resulting structures, are described. In an example, a semiconductor structure includes a trench disposed in an inter-layer dielectric (ILD) layer. The trench has sidewalls, a bottom and a top. A U-shaped metal seed layer is disposed at the bottom of the trench and along the sidewalls of the trench but substantially below the top of the trench. A metal fill layer is disposed on the U-shaped metal seed layer and fills the trench to the top of the trench. The metal fill layer is in direct contact with dielectric material of the ILD layer along portions of the sidewalls of the trench above the U-shaped metal seed layer.

### TECHNICAL FIELD

Embodiments of the invention are in the field of semiconductor structures and processing and, in particular, bottom-up fill approaches for forming metal features of semiconductor structures, and the resulting structures.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips.

In a first aspect, integrated circuits commonly include electrically conductive microelectronic structures, which are known in the arts as vias, to electrically connect metal lines or other interconnects above the vias to metal lines or other interconnects below the vias. Vias are typically formed by a lithographic process. Representatively, a photoresist layer may be spin coated over a dielectric layer, the photoresist layer may be exposed to patterned actinic radiation through a patterned mask, and then the exposed layer may be developed in order to form an opening in the photoresist layer. Next, an opening for the via may be etched in the dielectric layer by using the opening in the photoresist layer as an etch mask. This opening is referred to as a via opening. Finally, the via opening may be filled with one or more metals or other conductive materials to form the via.

In the past, the sizes and the spacing of vias has progressively decreased, and it is expected that in the future the sizes and the spacing of the vias will continue to progressively decrease, for at least some types of integrated circuits (e.g., advanced microprocessors, chipset components, graphics chips, etc.). One measure of the size of the vias is the critical dimension of the via opening. One measure of the spacing of the vias is the via pitch. Via pitch represents the center-to-center distance between the closest adjacent vias. When patterning extremely small vias with extremely small pitches by such lithographic processes, several challenges present themselves, especially when the pitches are around 70 nanometers (nm) or less and/or when the critical dimensions of the via openings are around 35 nm or less.

One such challenge is that the overlay between the vias and the overlying interconnects, and the overlay between the vias and the underlying landing interconnects, generally need to be controlled to high tolerances on the order of a quarter of the via pitch. As via pitches scale ever smaller over time, the overlay tolerances tend to scale with them at an even greater rate than lithographic equipment is able to keep up. Another such challenge is that the critical dimensions of the via openings generally tend to scale faster than the resolution capabilities of the lithographic scanners. Shrink technologies exist to shrink the critical dimensions of the via openings. However, the shrink amount tends to be limited by the minimum via pitch, as well as by the ability of the shrink process to be sufficiently optical proximity correction (OPC) neutral, and to not significantly compromise line width roughness (LWR) and/or critical dimension uniformity (CDU). Yet another such challenge is that the LWR and/or CDU characteristics of photoresists generally need to improve as the critical dimensions of the via openings decrease in order to maintain the same overall fraction of the critical dimension budget. However, currently the LWR and/or CDU characteristics of most photoresists are not improving as rapidly as the critical dimensions of the via openings are decreasing. A further such challenge is that the extremely small via pitches generally tend to be below the resolution capabilities of even extreme ultraviolet (EUV) lithographic scanners. As a result, commonly two, three, or more different lithographic masks may be used, which tend to increase the costs. At some point, if pitches continue to decrease, it may not be possible, even with multiple masks, to print via openings for these extremely small pitches using EUV scanners. Furthermore, metal fill of such openings can be even more problematic.

Thus, improvements are needed in the area of via and related interconnect manufacturing technologies.

In a second aspect, multi-gate transistors, such as tri-gate transistors, have become more prevalent as device dimensions continue to scale down. In conventional processes, tri-gate or other non-planar transistors are generally fabricated on either bulk silicon substrates or silicon-on-insulator substrates. In some instances, bulk silicon substrates are preferred due to their lower cost and compatibility with the existing high-yielding bulk silicon substrate infrastructure. Scaling multi-gate transistors has not been without consequence, however. As the dimensions of these fundamental building blocks of microelectronic circuitry are reduced and as the sheer number of fundamental building blocks fabricated in a given region is increased, the constraints on the semiconductor processes used to fabricate these building blocks have become overwhelming.

Thus, improvements are needed in the area of non-planar transistor manufacturing technologies.

### BRIEF DESCRIPTION OF THE DRAWINGS

FIG. 1 illustrates a state of the art processing scheme for filling a dielectric trench or via structure with a metal.

FIG. 2A illustrates various operations in a processing scheme using a bottom-up fill approach based on selective deposition at the bottom of a trench or via, in accordance with an embodiment of the present invention.

FIG. 2B illustrates various operations in a processing scheme using a bottom-up fill approach based on selective deposition for a single damascene process that does not involve self-aligned patterning, in accordance with an embodiment of the present invention.

FIG. 2C illustrates various operations in a processing scheme using a bottom-up fill approach based on selective deposition for a single damascene process that also involves self-aligned patterning, in accordance with an embodiment of the present invention.

FIG. 2D illustrates various operations in a processing scheme using a bottom-up fill approach based on selective deposition for a dual damascene process that also involves self-aligned patterning, in accordance with an embodiment of the present invention.

FIG. 3 illustrates various operations in a processing scheme using a bottom-up fill approach and passivation assistance from a self-assembled monolayer, in accordance with an embodiment of the present invention.

FIG. 4 illustrates various operations in another processing scheme using a bottom-up fill approach and passivation assistance from a self-assembled monolayer, in accordance with another embodiment of the present invention.

FIG. 5 illustrates several drawbacks of state of the art deposition and recess etch approaches to feature filling of semiconductor structures.

FIG. 6A illustrates a selective trench fill scheme, in accordance with an embodiment of the present invention.

FIG. 6B illustrates a general motif of a chemical precursor design with two diazabutadiene ligands, in accordance with an embodiment of the present invention.

FIG. 7A illustrates a cross-sectional view of a non-planar semiconductor device, in accordance with an embodiment of the present invention.

FIG. 7B illustrates a plan view taken along the a-a′ axis of the semiconductor device of FIG. 7A, in accordance with an embodiment of the present invention.

FIG. 8 illustrates a computing device in accordance with one implementation of the invention.

FIG. 9 is an interposer implementing one or more embodiments of the invention.

### DESCRIPTION OF THE EMBODIMENTS

Bottom-up fill approaches for forming metal features of semiconductor structures, and the resulting structures, are described. In the following description, numerous specific details are set forth, such as specific integration and material regimes, in order to provide a thorough understanding of embodiments of the present invention. It will be apparent to one skilled in the art that embodiments of the present invention may be practiced without these specific details. In other instances, well-known features, such as integrated circuit design layouts, are not described in detail in order to not unnecessarily obscure embodiments of the present invention. Furthermore, it is to be understood that the various embodiments shown in the Figures are illustrative representations and are not necessarily drawn to scale.

One or more embodiments described herein are directed to bottom-up fill of metal features for semiconductor structures. In a first embodiment, a bottom-up fill approach involves bottom-up fill using selective deposition. In a second embodiment, bottom-up atomic layer deposition (ALD) and/or chemical vapor deposition (CVD) fill of metals and/or dielectrics is implemented as an enabler of gap fill for semiconductor device applications through inherent selectivity and geometrically defined passivation. One or more embodiments described herein enable pitch-independent seamless/gapless bottom-up fill with few defects, which directly translates to improved device reliability and yield.

In a first aspect of the present disclosure, embodiments are directed to bottom-up fill using selective deposition.

To provide context, filling of patterned trenches or holes becomes increasingly difficult when feature sizes shrink or aspect ratios increase. Conformal fill results in a seam that cannot be healed without applying extreme thermal conditions. Many fill processes actually have some degree of non-conformality due to a difference in deposition rate on the horizontal field compared to the perpendicular sidewall, which can result in an even more exaggerated seam or void.

In accordance with one or more embodiments of the present invention, a trench or hole designated to be filled is designed such that the horizontal surface at the bottom is chemically different from the surfaces of the perpendicular sidewall surfaces (or at least a substantial portion of the sidewalls surfaces, especially the upper portions of the sidewall surfaces) and horizontal field adjacent to the features. In one such embodiment, a precursor that selectively deposits material on the bottom surface is implemented to provide film growth from the bottom of the feature to the top of the feature without leaving any seam or gap.

More specifically, embodiments of the present invention, when implemented, can result in filled features that are absent seams or gaps that would otherwise lead to device reliability issues. Such a selective deposition method may be successfully implemented independent of feature size and pitch, typically with no to few defects. By contrast, known bottom-up fill methods that utilize surface modification by ion-implantation are often limited to patterns with unvarying size and pitch. Meanwhile, electroless chemistry may also be used for bottom-up fill, but the process is notoriously difficult to maintain in control due to undesirable particle formation.

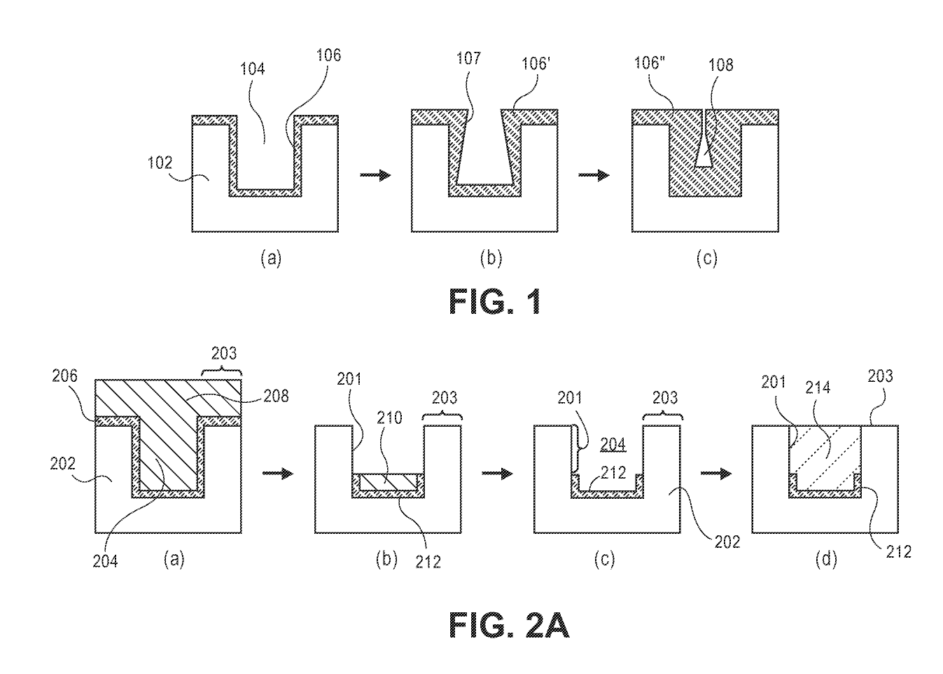

To provide an illustrative comparison, FIG. 1 illustrates a state of the art processing scheme for filling a dielectric trench or via structure with a metal. Referring to part (a) of FIG. 1, initial deposition of a metal layer 106 begins at a formed trench 104, e.g., in a dielectric layer 102. Bread-loafing or pinch-off (e.g., at points 107) of the metal fill occurs as deposition continues, providing metal layer 106′, as shown in part (b) of FIG. 1. Referring to part (c) of FIG. 1, completion of metal layer 106″ undesirably leaves a seam or gap 108 in the final structure.

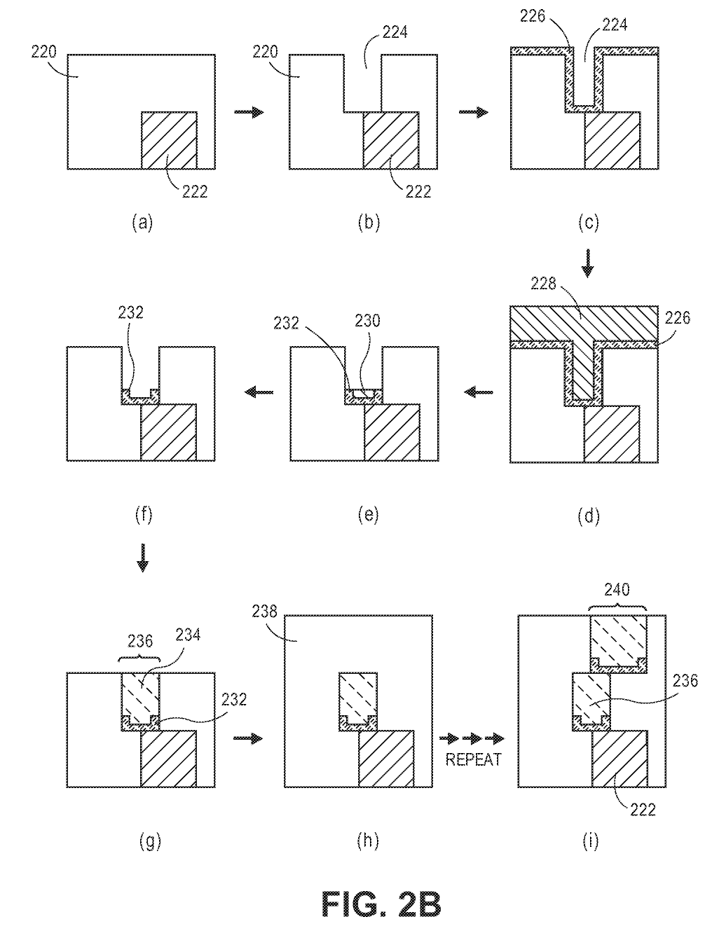

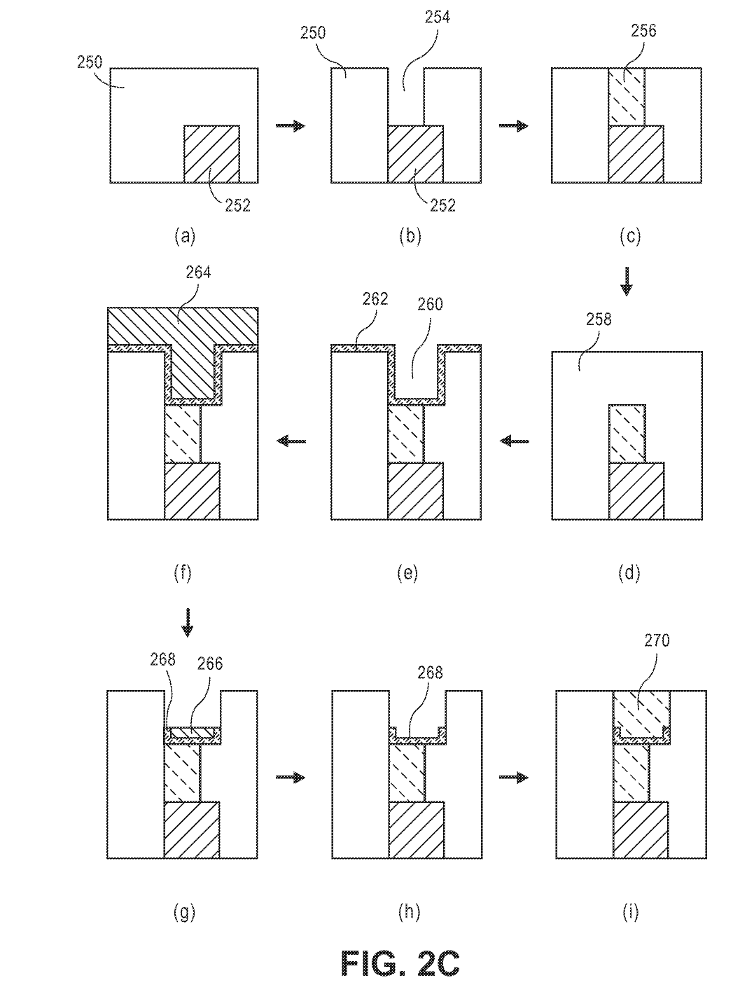

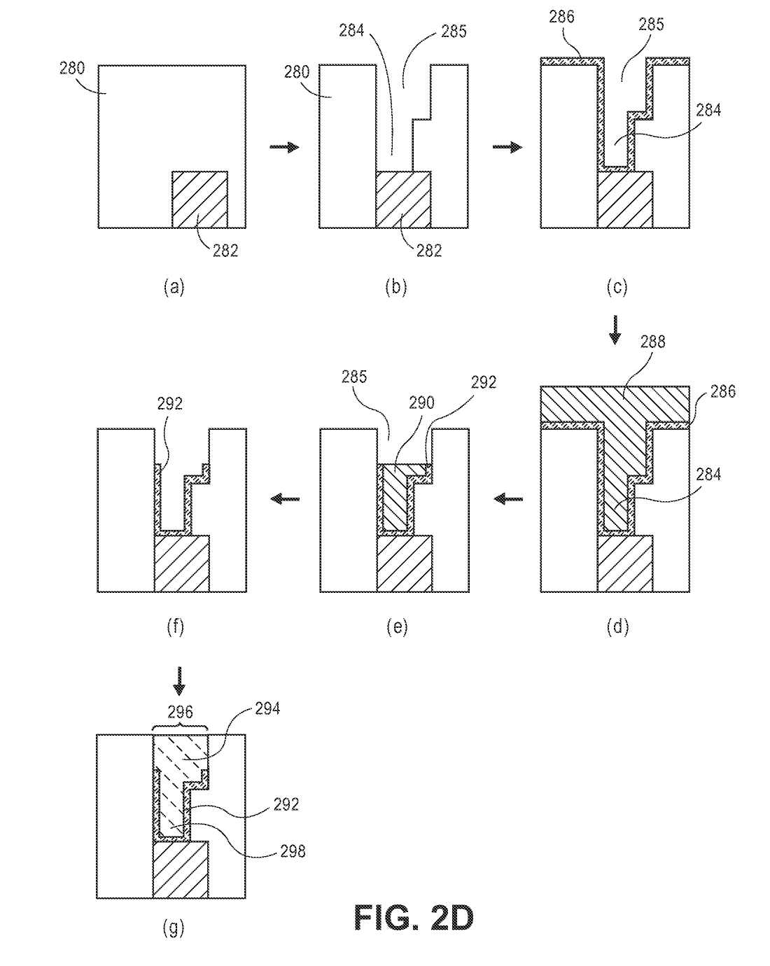

In contrast to FIG. 1, FIG. 2A illustrates various operations in a processing scheme using a bottom-up fill approach based on selective deposition at the bottom of a trench or via, in accordance with an embodiment of the present invention.

Referring to part (a) of FIG. 2A, a thin conformal metal seed layer 206 is deposited over a pattern, such as a trench 204, formed in an inter-layer dielectric (ILD) layer 202. In one embodiment, the seed layer 206 is an approximately 1-2 nanometer thick layer of tungsten, tungsten nitride, titanium nitride, ruthenium, or cobalt, as examples. Referring again to part (a) of FIG. 2A, a fill material 208 is deposited into the trench 204. In one such embodiment, an excess of the fill material 208 is deposited leading to some overburden in the field 203. In an embodiment, the fill material 208 is a material such as, but not limited to, silicon dioxide, a carbon hard-mask material, or tungsten metal. The fill material 208 may be deposited using techniques such as plasma-enhanced chemical vapor deposition (PECVD), atomic layer deposition (ALD), or spin-on deposition.

Referring to part (b) of FIG. 2A, the fill material 208 is partially removed to provide recessed fill material 210. The fill material 208 may be partially removed by, e.g., wet etch, dry etch, or chemical-mechanical polishing (CMP). Additionally, the seed layer 206 is removed from the field 203 and exposed sidewalls 201 of the trench 204 to provide recessed seed layer 212. Exposed portions of the seed layer 206 may be removed by, e.g., wet etch or dry etch. In an embodiment, as is depicted in part (b) of FIG. 2A, lower sidewall portions of the seed layer 206 are retained in the recessed seed layer 212, providing a U-shaped appearance. However, at least the upper sidewall portions 201 of the trench 204 are removed, leaving a U-shaped appearance but with recessed sidewalls that are below the top of the trench 204. It is to be appreciated that such a U-shaped structure may not be most optimal (as compared to a layer formed on only the bottom surface of the trench 204). Nonetheless, such a structure may be realistic for a fabrications scheme that provides some tolerance in the recess process.

In an embodiment, the U-shaped recessed seed layer 212 has sidewall portions with a height substantially below the top surface of the trench 204. For example, in one embodiment, the height of the sidewall portions of the U-shaped recessed seed layer 212 is less than 50% the height of the trench (i.e., the sidewall portions of the U-shaped recessed seed layer 212 are confined to the lower half of the height of the trench). In a specific embodiment, the height of the sidewall portions of the U-shaped recessed seed layer 212 is less than 25% the height of the trench (i.e., the sidewall portions of the U-shaped recessed seed layer 212 are confined to the lower quarter of the height of the trench).

In an embodiment, the fill material 208 is partially removed to provide recessed fill material 210 prior to removing the seed layer 206 from the field 203 and exposed sidewalls 201 of the trench 204 to provide recessed seed layer 212. In another embodiment, portions of the fill material 208 and the seed layer 206 are removed at substantially the same time, e.g., in the same process operation. However, in this latter embodiment, the process is extremely sensitive to process timing and may be difficult to control.

Referring to part (c) of FIG. 2A, recessed fill material 210 is removed to expose the recessed seed layer 212. The recessed fill material 210 may be removed by, e.g., wet etch or dry etch. It is to be appreciated that other approaches may lead to the structure of part (c) of FIG. 2A, which may be considered a starting point structure for a bottom-up fill approach. For example, in another embodiment, the seed layer 206 is recessed to provide the recessed seed layer 212 using an angled dry etch process in the absence of a fill material such as fill material 208. In either case, the result provides the recessed seed layer 212 as exposed at the bottom of trench 204. Upper sidewall portions 201 of the trench 204 (i.e., sidewall portions of the inter-layer dielectric layer 202) and field portions of the inter-layer dielectric layer 202 are also exposed, as is depicted in part (c) of FIG. 2A.

Referring to part (d) of FIG. 2A, a metal fill layer 214 is formed in the structure of part (c) of FIG. 2A. In an embodiment, the metal fill layer 214 is formed using selective deposition. In one such embodiment, the metal fill layer 214 is formed in a bottom-up fill process in that the growth occurs on the recessed seed layer 212 but not on the ILD surfaces 201 or 203. The fill may be controlled to the level of the field 203, or the growth may be performed in excess and then planarized back (e.g., by a CMP process). In either case, no seam or gap (such as seem or gap 108 described in association with FIG. 1) is formed. In an embodiment, the metal fill layer 214 is formed by an atomic layer or chemical vapor deposition process used to selectively deposit material that grows only on the seed layer 212, resulting in seamless bottom-up fill of the trench 204. In one such embodiment, the metal fill layer 214 is composed of a conductive material such as, but not limited to, Al, Ti, Zr, Hf, V, Ru, Co, Ni, Pd, Pt, Cu, Ag, Au or alloys thereof. Typical trench aspect ratios are approximately in the range of 2:1 to 10:1 with top dimensions approximately in the range of 6-40 nanometers.

Thus, in an embodiment, a semiconductor structure includes a trench 204 disposed in an inter-layer dielectric (ILD) layer 202. The trench has sidewalls, a bottom and a top. A U-shaped metal seed layer 212 is disposed at the bottom of the trench and along the sidewalls of the trench but substantially below the top of the trench. A metal fill layer 214 is disposed on the U-shaped metal seed layer 212 and fills the trench 204 to the top of the trench. The metal fill layer 214 is in direct contact with dielectric material of the ILD layer 202 along portions of the sidewalls of the trench above the U-shaped metal seed layer 212.

Although only one trench 204 is shown in the FIG. 2A processing series, in an embodiment, a starting structure may be patterned in a grating-like pattern with trenches spaced at a constant pitch and having a constant width. The pattern, for example, may be fabricated by a pitch halving or pitch quartering approach. Some of the trenches may be associated with underlying vias or lower level metallization lines. For example, it is to be understood that the layers and materials described in association with FIG. 2A are typically formed on or above an underlying semiconductor substrate or structure, such as underlying device layer(s) of an integrated circuit. In an embodiment, an underlying semiconductor substrate represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. Furthermore, the structures depicted in FIG. 2A may be fabricated on underlying lower level interconnect layers. The resulting structure of part (d) of FIG. 2A may subsequently be used as a foundation for forming subsequent metal line/via and ILD layers. Alternatively, the structure of part (d) of FIG. 2A may represent the final metal interconnect layer in an integrated circuit. Furthermore, it is to be appreciated that the above examples do not include etch-stop or metal capping layers in the Figures that may otherwise be necessary for patterning. However, for clarity, such layers are not included in the Figures since they do not impact the overall bottom-up fill concept.

Exemplifying a first specific application of the process described in association with FIG. 2A, FIG. 2B illustrates various operations in a processing scheme using a bottom-up fill approach based on selective deposition for a single damascene process that does not involve self-aligned patterning, in accordance with an embodiment of the present invention.

Referring to part (a) of FIG. 2B, inter-layer dielectric (ILD) layer 220 deposition is performed on an underlying metallization structure that includes a metal line or other feature 222. A via etch and breakthrough process is then performed to form a via opening 224 in the ILD layer 220 and to expose the metal line or other feature 222, as is depicted in part (b) of FIG. 2B. Referring to part (c) of FIG. 2B, a metal seed layer 226 is formed in the trench 224. A sacrificial filler material 228 is then formed on the structure of part (c), as is depicted in part (d) of FIG. 2B. Referring to part (e) of FIG. 2B, partial recess and etch of the sacrificial filler material 228 and the metal seed layer 226 is performed to provide recessed fill material layer 230 and recessed metal seed layer 232. The recessed fill material layer 230 is then removed to leave the recessed metal seed layer 232 exposed, as is depicted in part (f) of FIG. 2B. Referring to part (g) of FIG. 2B, a metal fill layer 234 is formed on the recessed metal seed layer 232 by selective deposition, e.g., by a bottom-up fill process, to form a via structure 236. An ILD layer 238 is then formed on the structure of part (g) of FIG. 2B, as is depicted in part (h) of FIG. 2B. Referring to part (i) of FIG. 2B, the process of parts (a)-(g) is repeated to provide a metal line feature 240 above and electrically coupled to the via structure 236. The resulting structure may represent a portion of a back end interconnect structure for a semiconductor device.

Exemplifying a second specific application of the process described in association with FIG. 2A, FIG. 2C illustrates various operations in a processing scheme using a bottom-up fill approach based on selective deposition for a single damascene process that also involves self-aligned patterning, in accordance with an embodiment of the present invention.

Referring to part (a) of FIG. 2C, inter-layer dielectric (ILD) layer 250 deposition is performed on an underlying metallization structure that includes a metal line or other feature 252. A via etch and breakthrough process is then performed to form a via opening 254 in the ILD layer 250 and to expose the metal line or other feature 252, as is depicted in part (b) of FIG. 2C. Referring to part (c) of FIG. 2C, selective deposition of a metal fill layer 256 is performed to fill trench 254. An ILD layer 258 is then formed on the structure of part (c) of FIG. 2C, as is depicted in part (d) of FIG. 2C. Referring to part (e) of FIG. 2C, a trench 260 is then formed in the ILD layer 258 and a metal seed layer 262 is then formed in the trench 260. A sacrificial filler material 264 is then formed on the structure of part (e), as is depicted in part (f) of FIG. 2C. Referring to part (g) of FIG. 2C, partial recess and etch of the sacrificial filler material 264 and the metal seed layer 262 is performed to provide recessed fill material layer 266 and recessed metal seed layer 268. The recessed fill material layer 266 is then removed to leave the recessed metal seed layer 268 exposed, as is depicted in part (h) of FIG. 2C. Referring to part (i) of FIG. 2C, a metal fill layer 270 is formed on the recessed metal seed layer 266 by selective deposition, e.g., by a bottom-up fill process. The resulting structure may represent a portion of a back end interconnect structure for a semiconductor device. With reference again to the process flow of FIG. 2C, it is to be appreciated that if no seed layer is present over an exposed ILD area within the trench during deposition, the resulting structure may contain an unwanted air-gap. However, such an air gap may not form if lateral growth (“mushrooming”) is sufficiently fast.

Exemplifying a third specific application of the process described in association with FIG. 2A, FIG. 2D illustrates various operations in a processing scheme using a bottom-up fill approach based on selective deposition for a dual damascene process that also involves self-aligned patterning, in accordance with an embodiment of the present invention.

Referring to part (a) of FIG. 2D, inter-layer dielectric (ILD) layer 280 deposition is performed on an underlying metallization structure that includes a metal line or other feature 282. A via and trench etch and breakthrough process is then performed to form a via opening 284 and a trench (metal line) opening 285 in the ILD layer 280 and to expose the metal line or other feature 282, as is depicted in part (b) of FIG. 2D. Referring to part (c) of FIG. 2D, a metal seed layer 286 is formed in the via opening 284 and in the trench opening 285. A sacrificial filler material 288 is then formed on the structure of part (c), as is depicted in part (d) of FIG. 2D. Referring to part (e) of FIG. 2D, partial recess and etch of the sacrificial filler material 288 and the metal seed layer 286 is performed to provide recessed fill material layer 290 and recessed metal seed layer 292. In one embodiment, as shown, the recessing is terminated within the trench opening 285, i.e., prior to exposure of the via opening 284. The recessed fill material layer 290 is then removed to leave the recessed metal seed layer 292 exposed, as is depicted in part (f) of FIG. 2D. Referring to part (g) of FIG. 2D, a metal fill layer 294 is formed on the recessed metal seed layer 292 by selective deposition, e.g., by a bottom-up fill process, to form a metal line 296 and via structure 298. In an embodiment, the growth rate of the metal fill layer 294 from the bottom is greater than or the same as the growth rate on the sides of the via in order to ensure suitable filling of the dual damascene structure. The resulting structure may represent a portion of a back end interconnect structure for a semiconductor device.

With reference again to the process flow of FIG. 2D, it is to be appreciated that if no seed layer is present over an exposed ILD area within the trench during deposition, the resulting structure may contain an unwanted air-gap. However, such an air gap may not form if lateral growth is sufficiently fast. The same challenge is amplified in schemes with dual damascene patterning that do not use self-alignment techniques. With reference again to FIG. 2D, in an embodiment, the fill of the trench in the perpendicular direction is important since filling vias bottom up does not necessarily allow for effective filling of very long trenches.

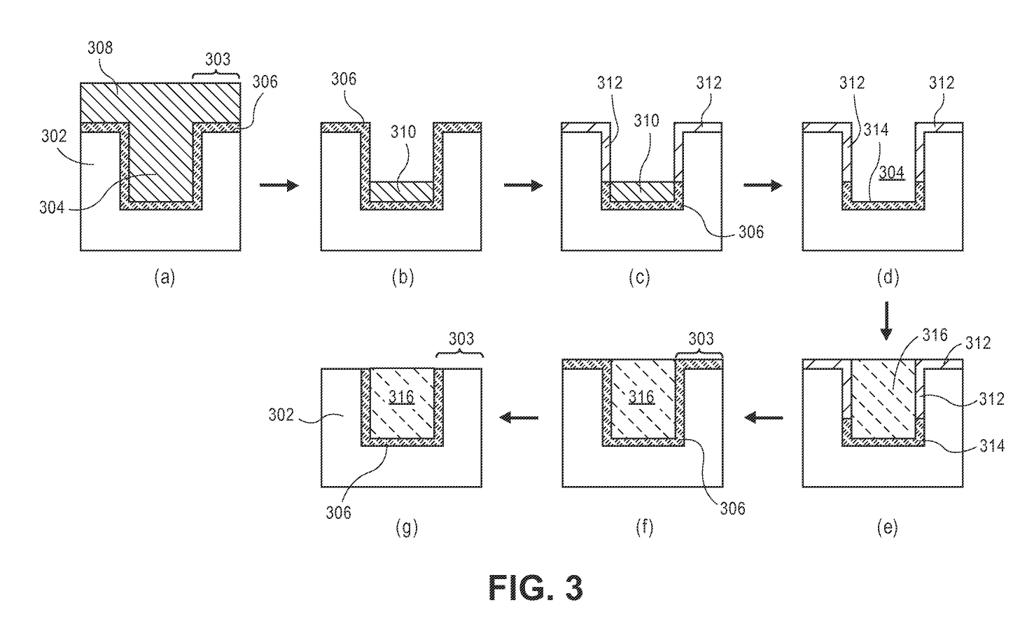

Other processing schemes involving bottom-up fill from selective deposition implement passivation assistance from a self-assembled monolayer. In a first such example, FIG. 3 illustrates various operations in a processing scheme using a bottom-up fill approach and passivation assistance from a self-assembled monolayer, in accordance with an embodiment of the present invention.

Referring to part (a) of FIG. 3, a thin conformal metal seed layer 306 is deposited over a pattern, such as a trench 304, formed in an inter-layer dielectric (ILD) layer 302. A fill material 308 is deposited into the trench 304. In one such embodiment, an excess of the fill material 308 is deposited leading to some overburden in the field 303. In one embodiment, the metal seed layer 306 is an approximately 1-2 nanometer thick layer of tungsten, titanium nitride, ruthenium, or cobalt, as examples. In one embodiment, the fill material 308 is a material such as, but not limited to, silicon dioxide, a carbon hard-mask material, or tungsten metal. The fill material 308 may be deposited using techniques such as plasma-enhanced chemical vapor deposition (PECVD), atomic layer deposition (ALD), or spin-on deposition.

Referring to part (b) of FIG. 3, partial recess and etch of the sacrificial filler material 308 is performed to provide recessed fill material layer 310. However, the metal seed layer 306 is not recessed. In an embodiment, the fill material layer 308 is partially removed by wet etch, dry etch, or chemical-mechanical polishing (CMP).

Referring to part (c) of FIG. 3, exposed portions of the metal seed layer 306 (i.e., portions not protected by the recessed fill material layer 310) are passivated with, e.g., a self-assembled monolayer (SAM), to form passivated portions 312 of the metal seed layer 306. In an embodiment, the SAM is formed by exposing the structure of part (b) of FIG. 3 to SAM-forming molecules in the vapor phase, or molecules dissolved in solvent. For example, in one such embodiment, the exposed portions of the metal seed layer 306 are passivated with octadecylphosphonic acid (ODPA) or dodecylthiol.

Referring to part (d) of FIG. 3, the recessed fill material layer 310 is removed, e.g., by wet or dry etch, leaving exposed an unpassivated portion 314 of the metal seed layer 306 at the bottom of the trench 304. An atomic layer or chemical vapor deposition process is then used to selectively deposit a metal fill material 316 that grows only on the unpassivated portion 314 of the metal seed layer 306, resulting in seamless bottom-up fill of the trench 304, as is depicted in part (e) of FIG. 3.

Referring to part (f) of FIG. 3, the SAM passivation layer on portions 312 of the metal seed layer 306 are removed to leave metal seed layer 306 and metal fill material 316. In an embodiment, the the SAM passivation layer is removed by chemical or thermal treatment. The portions of the metal seed layer 306 and the metal fill material 316 that overburden the field 303 are then polished (e.g., by CMP) such that all surfaces are flush with one another, as is depicted in part (g) of FIG. 3. The resulting structure may represent a portion of a back end interconnect structure for a semiconductor device. It is to be appreciated that, in an embodiment, the SAM layer 312 may also be retained and incorporated into the final structure.

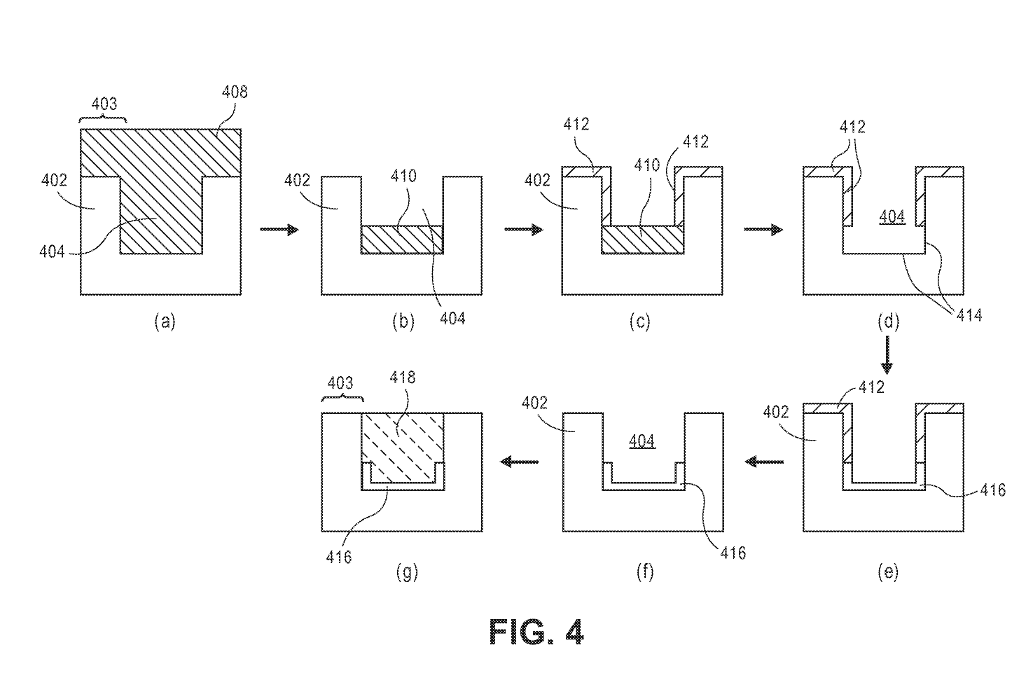

In a second such example, FIG. 4 illustrates various operations in another processing scheme using a bottom-up fill approach and passivation assistance from a self-assembled monolayer, in accordance with another embodiment of the present invention.

Referring to part (a) of FIG. 4, a fill material 408 is deposited into a trench 404 formed in an inter-layer dielectric (ILD) layer 402. In one such embodiment, an excess of the fill material 408 is deposited leading to some overburden in the field 403. In one embodiment, the fill material 408 is a material such as, but not limited to, silicon dioxide, a carbon hard-mask material, or tungsten metal. The fill material 408 may be deposited using techniques such as plasma-enhanced chemical vapor deposition (PECVD), atomic layer deposition (ALD), or spin-on deposition.

Referring to part (b) of FIG. 4, partial recess and etch of the sacrificial filler material 408 is performed to provide recessed fill material layer 410. In an embodiment, the fill material layer 408 is partially removed by wet etch, dry etch, or chemical-mechanical polishing (CMP).

Referring to part (c) of FIG. 4, exposed portions of the ILD material 402 (i.e., portions not protected by the recessed fill material layer 410) are passivated with, e.g., a self-assembled monolayer (SAM), to form passivated portions 412 of the ILD material 402, including sidewall portions of the trench 404.

In an embodiment, the SAM is formed by exposing the structure of part (b) of FIG. 4 to SAM-forming molecules in the vapor phase, or molecules dissolved in solvent. For example, in one such embodiment, the exposed portions of the ILD material 402 are passivated with octadecyltrichlorosilane (ODTCS).

Referring to part (d) of FIG. 4, the recessed fill material layer 410 is removed, e.g., by wet or dry etch, leaving exposed an unpassivated portion 414 of the ILD material 402 at the bottom of the trench 404. An atomic layer or chemical vapor deposition process is then used to selectively deposit a metal seed layer 416 that grows only on the unpassivated portion 414 of the ILD material 402.

Referring to part (f) of FIG. 4, the SAM passivation layer on portions 412 of the ILD material 402 are removed to leave metal seed layer 416 at the bottom of the trench 404. In an embodiment, the the SAM passivation layer is removed by chemical or thermal treatment.

Referring to part (g) of FIG. 4, an atomic layer or chemical vapor deposition process is then used to selectively deposit a metal fill material 418 that grows only on the metal seed layer 416, resulting in seamless bottom-up fill of the trench 404. Portions of the metal fill material 418 that overburden the field 403 are then polished (e.g., by CMP) such that all surfaces are flush with one another, as is depicted in part (g) of FIG. 4. The resulting structure may represent a portion of a back end interconnect structure for a semiconductor device.

Referring generally to FIGS. 2A-2D, 3 and 4, in an embodiment, as used throughout the present description, interlayer dielectric (ILD) material is composed of or includes a layer of a dielectric or insulating material. Examples of suitable dielectric materials include, but are not limited to, oxides of silicon (e.g., silicon dioxide (SiO₂)), doped oxides of silicon, fluorinated oxides of silicon, carbon doped oxides of silicon, various low-k dielectric materials known in the arts (e.g., those materials with a dielectric constant less than that of silicon dioxide), and combinations thereof. The interlayer dielectric material may be formed by conventional techniques, such as, for example, chemical vapor deposition (CVD), physical vapor deposition (PVD), or by other deposition methods. The interconnect lines (metal lines and vias structures) formed in the ILD material are also sometimes referred to in the art as traces, wires, lines, metal, or simply interconnect.

In a second aspect of the present disclosure, embodiments are directed to bottom-up atomic layer deposition (ALD) and chemical vapor deposition (CVD) fill of metals and dielectrics as an enabler of gapfill for semiconductor device applications through inherent selectivity and geometrically defined passivation. In an exemplary embodiment, a method for the bottom-up fill (BUF) of high aspect ratio features with metals or dielectrics to enable etchless recess for 10 nm technology nodes and smaller is described.

To provide general context, conventional trench fill is obtained by deposition of a liner, followed by a conductive metal or an insulator. The conductive metal or the insulator is deposited in excess and is subsequently planarized and recessed as needed. Some of the limitations of such a deposition and recess approach include local roughness of the etched material and imperfect selectivity to the liners used to improve the adhesion of the fill materials. Such limitations can lead to corrosion issues during downstream processing.

In accordance with one or more embodiments of the present invention, approaches for addressing gap-fill challenges critical to enable the 10 nm technology node and below are provided. Moreover, one or more embodiments herein offer a way to improve within die recess and eliminate corrosion risks due to imperfect etch selectivity between liner and fill material. More specifically, one or more embodiments combine inherent chemical selectivity in atomic layer deposition (ALD) or chemical vapor deposition processes (CVD) together with geometrically defined passivation schemes to achieve bottom-up gap-fill. One or more embodiments address needs such as “etchless” metal or dielectric recess for pitch doubling or pitch quartering integration schemes, or dielectric plugging in contact integration schemes.

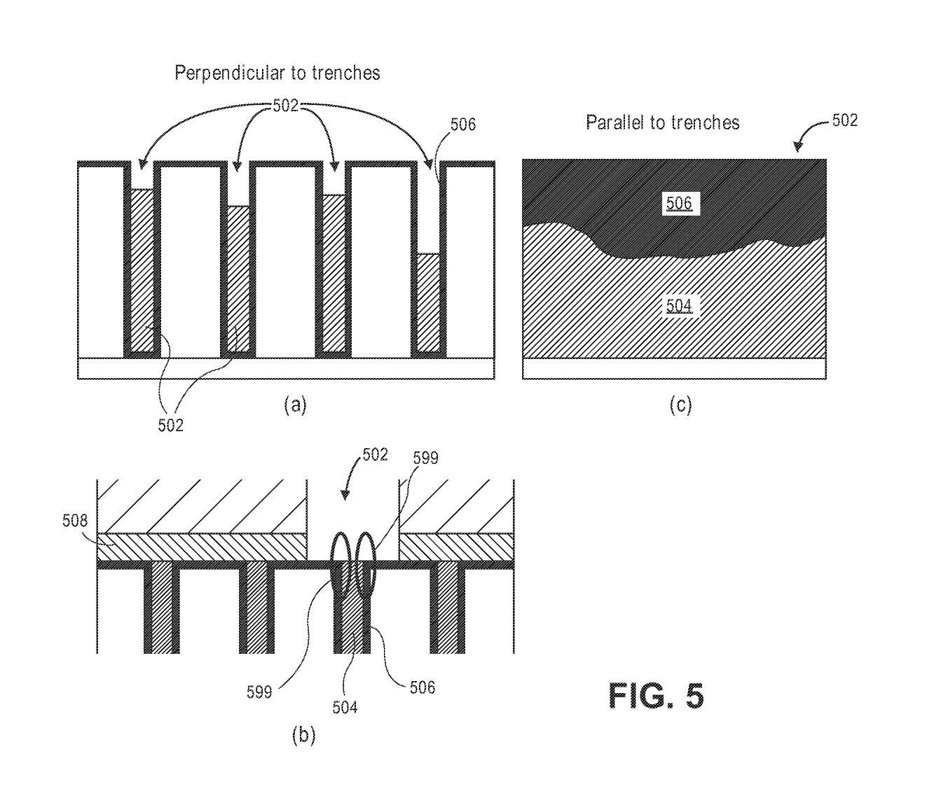

To provide more specific context, state of the art metal or dielectric vertical fill targets are obtained with a “deposition and recess etch” approach. This approach is prone to local variability in height and roughness as well as imperfect etch selectivity to other materials in the stack during subsequent processing. As an example, FIG. 5 illustrates several drawbacks of state of the art deposition and recess etch approaches to feature filling of semiconductor structures.

Referring to part (a) of FIG. 5, recess non-uniformity for a metal fill and recess approach is depicted. The left-hand image of part (a) of FIG. 5 illustrates a view perpendicular to a plurality of trenches 502 requiring material fill, even in the case that a conformal trench liner material 506 is first formed. The actual fill 504 (whether a conductor or other material) varies from trench to trench. Furthermore, as shown in the right-hand image of part (a) of FIG. 5, as taken parallel along a single trench 502, the actual fill 504 can vary within the single trench 502.

Referring to part (b) of FIG. 5, corrosion of adhesion liner materials is illustrated. Conventional CVD or ALD damascene fill of trenches involves the use of an adhesion liner 506, which is typically a metal nitride material. The liner 506 may be incompatible with a cleans process typically used to remove a next layer hardmask material 508, leading to corrosion and loss of functionality (e.g., at regions 599).

To overcome the shortcomings described in association with FIG. 5, in accordance with an embodiment of the present invention, regions of a patterned wafer or structure are passivated where deposition is not wanted. The passivation is based on geometric selectivity, e.g., in the field and a set depth into each of the patterned features. In one embodiment, such passivation is achieved using a plasma implant deposition of an ultrathin layer of carbon or phosphorus. In an embodiment, subsequent ALD or CVD growth of either a metal or a dielectric film is performed in the bottom of patterned features up to a targeted height, without growth occurring in the field. In some embodiments, growth may occur on the bottom and side-walls of the feature (but not in the field) to provide a “feature-only fill” approach.

In a specific embodiment, in the case of metal bottom-up fill (BUF) or metal feature-only fill, the fill is achieved using an inherent selectivity of some metal precursors for growth on the metallic surface of a liner (such as a W or Co liner) formed over non-conducting surfaces. There are currently no known methods for the BUF of pure metals. Embodiments described herein may need only a conductive surface exposed at a bottom of a feature to fill selectively with an appropriately chosen metal CVD or ALD process. In another specific embodiment, in the case of dielectrics, BUF or “feature-only fill” is achieved with a variety of thermal ALD or CVD processes which nucleate preferentially on the unpassivated surface at the bottom of a feature. The deposition of the “feature-only fill” material may be followed by an anneal operation to remove any seams. BUF of some dielectrics is possible with reflowable CVD materials but there are no known solutions for the BUF of metal oxides (e.g., HfO₂, Al₂O₃). In either case (metal or dielectric BUF), one or more BUF approaches described herein avoids pinch-off at the top of features commonly associated with line-of-sight physical deposition techniques (e.g., evaporation or sputter) or conformal deposition by ALD/CVD.

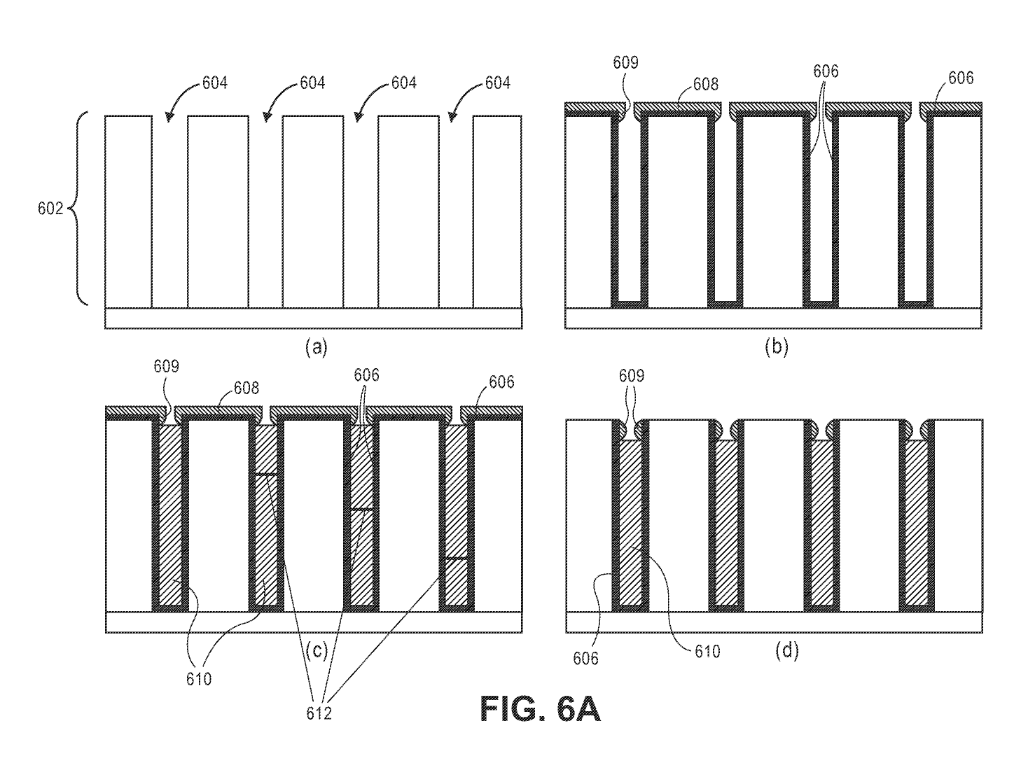

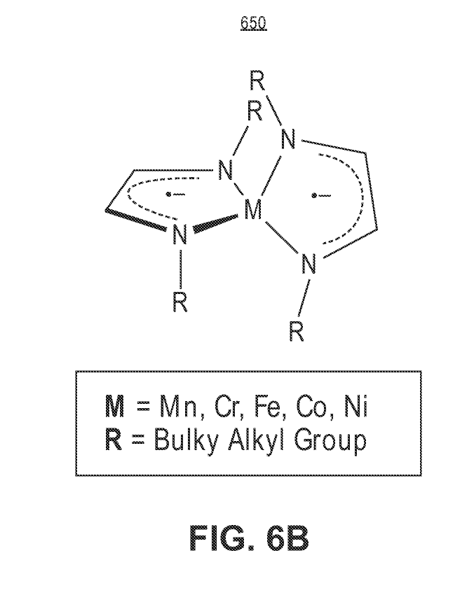

In an exemplary bottom up fill process flow consistent with the second aspect of the present disclosure, FIG. 6A illustrates a selective trench fill scheme, in accordance with an embodiment of the present invention.

Referring to part (a) of FIG. 6A, a plurality of trenches 604 is formed in a layer 602 of a semiconductor structure. The patterned layer 602 may be an inter-layer dielectric (ILD) layer and may be composed of an insulating material such as, but not limited to, a low-k dielectric material, a silicon oxide layer, a silicon oxynitride layer, a silicon nitride layer, etc. In a specific embodiment, each of the trenches 604 has an approximately 12 nanometer opening at the top and has an approximately 10:1 height:width aspect ratio. Other embodiments include each of the trenches 604 having an opening at the top approximately in the range 10-20 nm as well. Other embodiments include each of the trenches 604 having a height:width aspect ratio below 10:1.

Referring to part (b) of FIG. 6A, a thin conductive liner 606 is formed conformally over the structure of part (a) of FIG. 6A. In an embodiment, the thin conductive liner 606 is a conductive film. In one such embodiment, the thin conductive liner 606 is a conductive film suitable for catalyzing a subsequent deposition of a selective ALD/CVD material. In a specific embodiment, the thin conductive liner 606 is an ultrathin liner such as, but not limited to, a Co liner, a Ru liner, a TaN liner, a TiN liner, a W liner, or a WN liner. It is to be appreciated that selection of an appropriate thin conductive liner 606 can provide a stack that is more robust against a subsequent cleans attack.

Referring again to part (b) of FIG. 6A, a passivation layer 608/609 is formed and covers a field portion of the thin conductive liner 606 (covered with portion 608 of the passivation layer 608/609) and an upper portion of the sidewalls of the thin conductive liner 606 formed in the trench 604 (covered with portion 609 of the passivation layer 608/609). In an embodiment, the passivation layer 608/609 is a plasma implant passivated region. In one such embodiment, the passivation layer 608/609 is formed by a geometrically defined deposition of a carbon layer (e.g., formed from CH₄), a phosphorous layer (e.g., formed from PH₃) or a boron layer (e.g., formed from BF₃ or B₂H₆) at least in the field (horizontal region) using a plasma implant process. The passivation layer 608/609 may be further formed along an uppermost portion of the sidewalls of the trenches 604, as is depicted in part (b) of FIG. 6A. It is to be appreciated that the process may be tailored to extend the formation on the sidewalls to a selected depth into the trench 604.

Referring to part (c) of FIG. 6A, a trench fill material 610 is formed in the trenches 604. The trench fill material is formed in the trenches 604 at the exposed surfaces of the thin conductive liner 606. However, the fill is confined to those regions of the exposed surfaces of the thin conductive liner 606 since the fill process is selective against formation at locations where the passivation layer 608/609 is formed. Accordingly, in an embodiment, the presence of a carbon cap or phosphorous cap (e.g., as passivation layer 608/609) enables the selective growth of ALD/CVD films in only the trench 604 and not the field. Furthermore, the growth can further be confined to a level deeper within the trench if the passivation layer 608/609 is formed along a portion of the sidewalls of the trench. As an example, the fill material 610 in the trenches of part (c) of FIG. 6A is slightly recessed into the trenches 604 due to the presence of portion 609 of the passivation layer. Other exemplary level markers 612 are shown for illustrative purposes to show a possible lower fill levels in the case of increasingly extending portions 609 of the passivation layer (although the increasingly extending portions 609 of the passivation layer are not actually depicted in the Figure). That is, by tailoring the passivated region, different controlled heights for bottom up fill may be achieved, allowing for a recess-less process.

In an embodiment, the fill material 610 is a conductive material composed of a metal or metal alloy deposited by ALD or CVD processing. In another embodiment, the fill material 610 is a dielectric material such as a metal oxide deposited by ALD or CVD processing. In either case, in an embodiment, trench fill is achieved using a class of purposely designed metal ALD or CVD precursors that will only deposit on the conductive metal liner 606 inside the trench 604 and not on the passivated top surface 608/609. As mentioned above, depending on the degree of wrap-around for the plasma implant deposited passivation layer, the height of the metal fill inside the trench can be controlled.

Referring to part (d) of FIG. 6A, the portions of the passivation layer 608/609 and the thin conductive liner 606 that are on the field of the structure are removed. In one such embodiment, the portions of the passivation layer 608/609 and the thin conductive liner 606 that are on the field of the structure are removed by a chemical mechanical polishing process or a plasma ashing process. As exemplified in part (d) of FIG. 6A, in an embodiment, where the passivation layer 608/609 includes sidewall portions (609) below the planarization height, these portions may remain in the final structure. It is to be appreciated that an additional layer may be layer formed over the structure of part (d), but the sidewall portions 609 may be retained nonetheless.

In a specific embodiment, the selective trench fill scheme described in association with FIG. 6A is performed using a precursor having a chemical precursor design with two diazabutadiene ligands. As an example, FIG. 6B illustrates a general motif 650 of a chemical precursor design with two diazabutadiene ligands, in accordance with an embodiment of the present invention. Referring to FIG. 6B, the motif 650 is generally applicable to first row late-transition metals (e.g., M=Cr, Mn, Fe, Co, Ni), thus allowing trench fill with these elements. Some of these elements (e.g., Ni, Co and Cr) have attractively low resistivities for interconnect applications. The bulky substituent on nitrogen (e.g., R is typically ^{t}Bu or ⁱPr) sterically protects the metal center M from direct undesirable reactions with the plasma implant passivated (C, P or B) surfaces 609/609 while forming metal fill layer 610. It is to be appreciated that metal fill using the precursors referred to in FIG. 6B may result in films containing 0-10 atomic % C and/or 0-5 atomic % N.

In an embodiment, although not to be bound by theory, growth on the unpassivated metal (liner 606) surfaces in the trenches 652 is achieved by direct interaction of the backbone of the diazabutadiene ligand of motif 650 with the conducting sea of electrons on the metal surface 606, by nature of its well-known redox non-innocence. Other ALD/CVD processes for metals (including those for Cu) and dielectrics are known to preferentially grow on metallic surfaces, rendering this approach more general. Finally, in some embodiments, the plasma implant deposited passivation layer 608/609 on top of an otherwise catalytic surface (liner 606) is combined with an electroless metal growth process to achieve selective growth.

Thus, with reference again to FIGS. 6A and 6B, and in accordance with one or more embodiments of the present invention, unique geometric distribution of a plasma implant deposited passivating element (such as C or P) is used to enable bottom up fill of a patterned feature in a structure. The use of selective ALD/CVD deposition allows for superior gap fill at narrow critical dimensions (CDs) and allows deposition of recessed metal, therefore uniquely providing a recess-less process. In one embodiment, approaches described herein enable functionality and high performance of leading edge trigate transistor architectures.

Advantages to one or more of the embodiments described in association with the second aspect of the present disclosure may include but are not limited to, avoiding a recess etch of materials can improve the health of the fabricated devices, with benefits in both line resistance and RC performance. The ability to use an ALD or CVD selective deposition approach can eliminate typical impurities associated with electro-less chemistries (such as W, B, P) which otherwise adversely affect metal resistance.

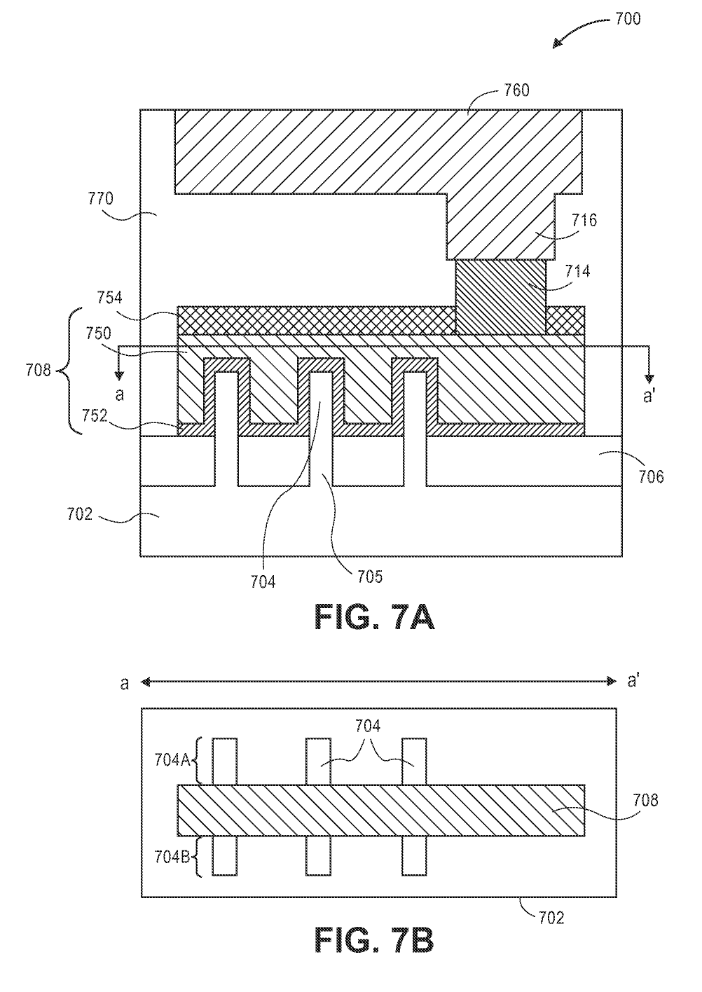

One or more embodiments described herein are directed to fabricating semiconductor devices, such as for PMOS and NMOS device fabrication. For example, one or more features of a semiconductor device is formed using a bottom-up metal fill approach, as described above. As an example of a completed device, FIGS. 7A and 7B illustrate a cross-sectional view and a plan view (taken along the a-a′ axis of the cross-sectional view), respectively, of a non-planar semiconductor device, in accordance with an embodiment of the present invention. As described below, metal gate structures can be filled by a bottom-up fill approach. Additionally, other features such as contacts and vias may also benefit from such approaches.

Referring to FIG. 7A, a semiconductor structure or device 700 includes a non-planar active region (e.g., a fin structure including protruding fin portion 704 and sub-fin region 705) formed from substrate 702, and within isolation region 706. A gate line 708 is disposed over the protruding portions 704 of the non-planar active region as well as over a portion of the isolation region 706. As shown, gate line 708 includes a gate electrode 750 and a gate dielectric layer 752. In one embodiment, gate line 708 may also include a dielectric cap layer 754. A gate contact 714, and overlying gate contact via 716 are also seen from this perspective, along with an overlying metal interconnect 760, all of which are disposed in inter-layer dielectric stacks or layers 770. Also seen from the perspective of FIG. 7A, the gate contact 714 is, in one embodiment, disposed over isolation region 706, but not over the non-planar active regions. In an embodiment, the pattern of fins is a grating pattern.

Referring to FIG. 7B, the gate line 708 is shown as disposed over the protruding fin portions 704. Source and drain regions 704A and 704B of the protruding fin portions 704 can be seen from this perspective. In one embodiment, the source and drain regions 704A and 704B are doped portions of original material of the protruding fin portions 704. In another embodiment, the material of the protruding fin portions 704 is removed and replaced with another semiconductor material, e.g., by epitaxial deposition. In either case, the source and drain regions 704A and 704B may extend below the height of dielectric layer 706, i.e., into the sub-fin region 705.

In an embodiment, the semiconductor structure or device 700 is a non-planar device such as, but not limited to, a fin-FET or a tri-gate device. In such an embodiment, a corresponding semiconducting channel region is composed of or is formed in a three-dimensional body. In one such embodiment, the gate electrode stacks of gate lines 708 surround at least a top surface and a pair of sidewalls of the three-dimensional body. The concepts may be extended to gate all around devices such as nanowire based transistors.

Substrate 702 may be composed of a semiconductor material that can withstand a manufacturing process and in which charge can migrate. In an embodiment, substrate 702 is a bulk substrate composed of a crystalline silicon, silicon/germanium or germanium layer doped with a charge carrier, such as but not limited to phosphorus, arsenic, boron or a combination thereof, to form active region 704. In one embodiment, the concentration of silicon atoms in bulk substrate 702 is greater than 97%. In another embodiment, bulk substrate 702 is composed of an epitaxial layer grown atop a distinct crystalline substrate, e.g. a silicon epitaxial layer grown atop a boron-doped bulk silicon mono-crystalline substrate. Bulk substrate 702 may alternatively be composed of a group III-V material. In an embodiment, bulk substrate 702 is composed of a III-V material such as, but not limited to, gallium nitride, gallium phosphide, gallium arsenide, indium phosphide, indium antimonide, indium gallium arsenide, aluminum gallium arsenide, indium gallium phosphide, or a combination thereof. In one embodiment, bulk substrate 702 is composed of a III-V material and the charge-carrier dopant impurity atoms are ones such as, but not limited to, carbon, silicon, germanium, oxygen, sulfur, selenium or tellurium.

Isolation region 706 may be composed of a material suitable to ultimately electrically isolate, or contribute to the isolation of, portions of a permanent gate structure from an underlying bulk substrate or isolate active regions formed within an underlying bulk substrate, such as isolating fin active regions. For example, in one embodiment, the isolation region 706 is composed of a dielectric material such as, but not limited to, silicon dioxide, silicon oxy-nitride, silicon nitride, or carbon-doped silicon nitride.

Gate line 708 may be composed of a gate electrode stack which includes a gate dielectric layer 752 and a gate electrode layer 750. In an embodiment, the gate electrode of the gate electrode stack is composed of a metal gate and the gate dielectric layer is composed of a high-K material. For example, in one embodiment, the gate dielectric layer is composed of a material such as, but not limited to, hafnium oxide, hafnium oxy-nitride, hafnium silicate, lanthanum oxide, zirconium oxide, zirconium silicate, tantalum oxide, barium strontium titanate, barium titanate, strontium titanate, yttrium oxide, aluminum oxide, lead scandium tantalum oxide, lead zinc niobate, or a combination thereof. Furthermore, a portion of gate dielectric layer may include a layer of native oxide formed from the top few layers of the substrate 702. In an embodiment, the gate dielectric layer is composed of a top high-k portion and a lower portion composed of an oxide of a semiconductor material. In one embodiment, the gate dielectric layer is composed of a top portion of hafnium oxide and a bottom portion of silicon dioxide or silicon oxy-nitride. In an embodiment, at least a portion of the metal gate electrode 750 is formed using a bottom-up fill approach as was described above in association with FIG. 6A. In other embodiments, processes such as described in association with FIGS. 2A-2D, 3 and 4 may be used.

Spacers associated with the gate electrode stacks may be composed of a material suitable to ultimately electrically isolate, or contribute to the isolation of, a permanent gate structure from adjacent conductive contacts, such as self-aligned contacts. For example, in one embodiment, the spacers are composed of a dielectric material such as, but not limited to, silicon dioxide, silicon oxy-nitride, silicon nitride, or carbon-doped silicon nitride.

Gate contact 714 and overlying gate contact via 716 may be composed of a conductive material. In an embodiment, one or more of the contacts or vias are composed of a metal species. The metal species may be a pure metal, such as tungsten, nickel, or cobalt, or may be an alloy such as a metal-metal alloy or a metal-semiconductor alloy (e.g., such as a silicide material). In an embodiment, a gate contact or gate contact via is formed by a via or interconnect bottom-up fill approach as was described above in association with FIGS. 2A-2D, 3 and 4. In other embodiments, bottom-up fill processes such as described in association with FIG. 6A may be used.

In an embodiment (although not shown), providing structure 700 involves formation of a contact pattern which is essentially perfectly aligned to an existing gate pattern while eliminating the use of a lithographic step with exceedingly tight registration budget. In one such embodiment, this approach enables the use of intrinsically highly selective wet etching (e.g., versus conventionally implemented dry or plasma etching) to generate contact openings. In an embodiment, a contact pattern is formed by utilizing an existing gate pattern in combination with a contact plug lithography operation. In one such embodiment, the approach enables elimination of the need for an otherwise critical lithography operation to generate a contact pattern, as used in conventional approaches. In an embodiment, a trench contact grid is not separately patterned, but is rather formed between poly (gate) lines. For example, in one such embodiment, a trench contact grid is formed subsequent to gate grating patterning but prior to gate grating cuts.

Furthermore, the gate stack structure 708 may be fabricated by a replacement gate process. In such a scheme, dummy gate material such as polysilicon or silicon nitride pillar material, may be removed and replaced with permanent gate electrode material. In one such embodiment, a permanent gate dielectric layer is also formed in this process, as opposed to being carried through from earlier processing. In an embodiment, dummy gates are removed by a dry etch or wet etch process. In one embodiment, dummy gates are composed of polycrystalline silicon or amorphous silicon and are removed with a dry etch process including use of SF₆. In another embodiment, dummy gates are composed of polycrystalline silicon or amorphous silicon and are removed with a wet etch process including use of aqueous NH₄OH or tetramethylammonium hydroxide. In one embodiment, dummy gates are composed of silicon nitride and are removed with a wet etch including aqueous phosphoric acid.

In an embodiment, one or more approaches described herein contemplate essentially a dummy and replacement gate process in combination with a dummy and replacement contact process to arrive at structure 700. In one such embodiment, the replacement contact process is performed after the replacement gate process to allow high temperature anneal of at least a portion of the permanent gate stack. For example, in a specific such embodiment, an anneal of at least a portion of the permanent gate structures, e.g., after a gate dielectric layer is formed, is performed at a temperature greater than approximately 600 degrees Celsius. The anneal is performed prior to formation of the permanent contacts.

Referring again to FIG. 7A, the arrangement of semiconductor structure or device 700 places the gate contact over isolation regions. Such an arrangement may be viewed as inefficient use of layout space. In another embodiment, however, a semiconductor device has contact structures that contact portions of a gate electrode formed over an active region. In general, prior to (e.g., in addition to) forming a gate contact structure (such as a via) over an active portion of a gate and in a same layer as a trench contact via, one or more embodiments of the present invention include first using a gate aligned trench contact process. Such a process may be implemented to form trench contact structures for semiconductor structure fabrication, e.g., for integrated circuit fabrication. In an embodiment, a trench contact pattern is formed as aligned to an existing gate pattern. By contrast, conventional approaches typically involve an additional lithography process with tight registration of a lithographic contact pattern to an existing gate pattern in combination with selective contact etches. For example, a conventional process may include patterning of a poly (gate) grid with separate patterning of contact features.

It is to be appreciated that not all aspects of the processes described above need be practiced to fall within the spirit and scope of embodiments of the present invention. For example, in one embodiment, dummy gates need not ever be formed prior to fabricating gate contacts over active portions of the gate stacks. The gate stacks described above may actually be permanent gate stacks as initially formed. Also, the processes described herein may be used to fabricate one or a plurality of semiconductor devices. The semiconductor devices may be transistors or like devices. For example, in an embodiment, the semiconductor devices are a metal-oxide semiconductor (MOS) transistors for logic or memory, or are bipolar transistors. Also, in an embodiment, the semiconductor devices have a three-dimensional architecture, such as a trigate device, an independently accessed double gate device, or a FIN-FET. One or more embodiments may be particularly useful for fabricating semiconductor devices at a 10 nanometer (10 nm) or smaller technology node.

It is to be appreciated that both above described aspects of embodiments of the present invention could be applicable to front end or back end processing technologies. Furthermore, embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory may be manufactured. Moreover, the integrated circuits or other microelectronic devices may be used in a wide variety of electronic devices known in the arts. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

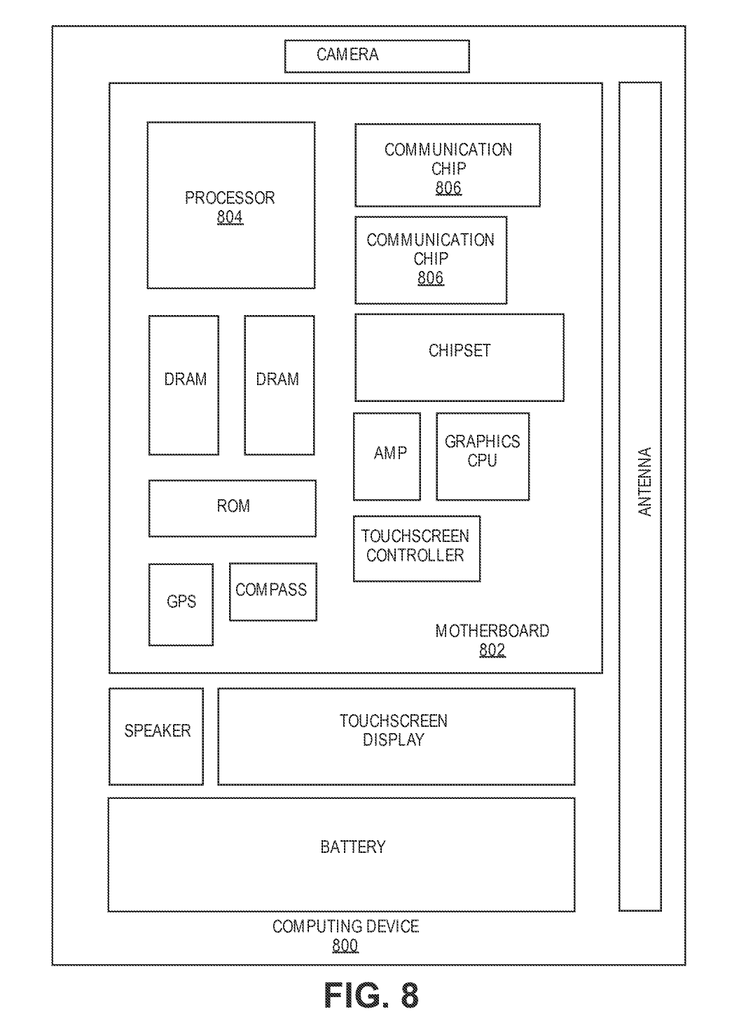

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor includes one or more metal features formed using a bottom-up fill approach, built in accordance with implementations of the invention. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with an embodiment of the present invention, the integrated circuit die of the communication chip includes one or more metal features formed using a bottom-up fill approach, built in accordance with implementations of the invention.

In further implementations, another component housed within the computing device 800 may contain an integrated circuit die that includes one or more metal features formed using a bottom-up fill approach, built in accordance with implementations of the invention.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

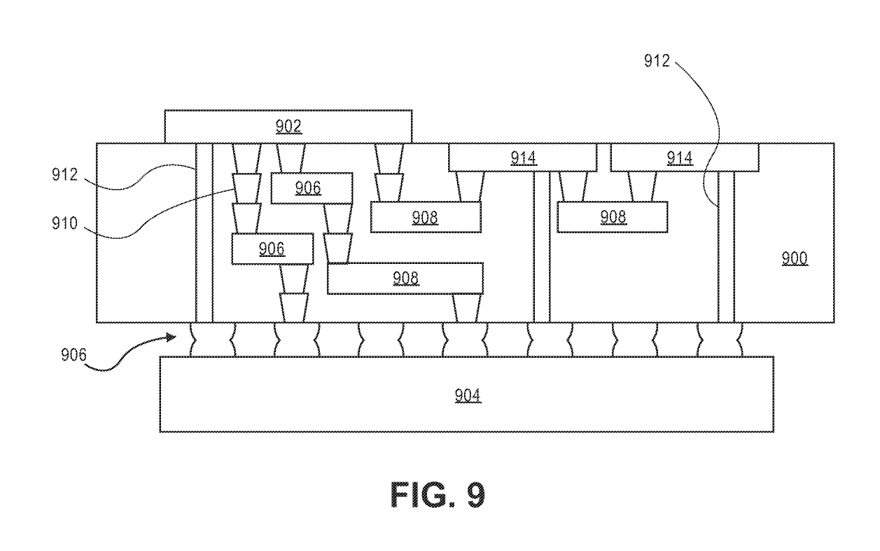

FIG. 9 illustrates an interposer 900 that includes one or more embodiments of the invention. The interposer 900 is an intervening substrate used to bridge a first substrate 902 to a second substrate 904. The first substrate 902 may be, for instance, an integrated circuit die. The second substrate 904 may be, for instance, a memory module, a computer motherboard, or another integrated circuit die. Generally, the purpose of an interposer 900 is to spread a connection to a wider pitch or to reroute a connection to a different connection. For example, an interposer 900 may couple an integrated circuit die to a ball grid array (BGA) 906 that can subsequently be coupled to the second substrate 904. In some embodiments, the first and second substrates 902/904 are attached to opposing sides of the interposer 900. In other embodiments, the first and second substrates 902/904 are attached to the same side of the interposer 900. And in further embodiments, three or more substrates are interconnected by way of the interposer 900.

The interposer 900 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 908 and vias 910, including but not limited to through-silicon vias (TSVs) 912. The interposer 900 may further include embedded devices 914, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 900. In accordance with embodiments of the invention, apparatuses or processes disclosed herein may be used in the fabrication of interposer 900.

Thus, embodiments of the present invention include bottom-up fill approaches for forming metal features of semiconductor structures, and the resulting structures.

In an embodiment, a semiconductor structure includes a trench disposed in an inter-layer dielectric (ILD) layer. The trench has sidewalls, a bottom and a top. A U-shaped metal seed layer is disposed at the bottom of the trench and along the sidewalls of the trench but substantially below the top of the trench. A metal fill layer is disposed on the U-shaped metal seed layer and fills the trench to the top of the trench. The metal fill layer is in direct contact with dielectric material of the ILD layer along portions of the sidewalls of the trench above the U-shaped metal seed layer.

In one embodiment, the trench is a metal line opening or a via opening in a back end metallization layer.

In one embodiment, the U-shaped metal seed layer has a thickness approximately in the range of 1 nanometer-2 nanometers.

In one embodiment, the U-shaped metal seed layer comprises a material selected from the group consisting of tungsten, titanium nitride, ruthenium, and cobalt.

In one embodiment, the U-shaped metal seed layer is disposed along the sidewalls of the trench to a height less than approximately 50% of the height of the trench.

In one embodiment, the U-shaped metal seed layer is disposed along the sidewalls of the trench to a height less than approximately 25% of the height of the trench.

In one embodiment, the metal fill layer is free from a seam or a gap.

In one embodiment, the dielectric material of the ILD layer is a low-k dielectric material.

In an embodiment, a method of fabricating a semiconductor structure includes forming a trench in an inter-layer dielectric (ILD) layer, the trench having sidewalls, a bottom and a top. The method also includes forming a U-shaped metal seed layer at the bottom of the trench and along the sidewalls of the trench but substantially below the top of the trench. The method also includes forming a metal fill layer on the U-shaped metal seed layer to fill the trench to the top of the trench, wherein the metal fill layer is formed selectively on the U-shaped metal seed layer.

In one embodiment, forming the U-shaped metal seed layer comprises forming a metal seed layer at the bottom of the trench and along the sidewalls of the trench to the top of the trench, forming a material fill layer on the metal seed layer, recessing the material fill layer to expose portions of the metal seed layer, removing the exposed portions of the metal seed layer to form the U-shaped metal seed layer, and removing the recessed material fill layer.

In one embodiment, forming the U-shaped metal seed layer comprises forming a metal seed layer at the bottom of the trench and along the sidewalls of the trench to the top of the trench, forming a material fill layer on the metal seed layer, recessing the material fill layer to expose portions of the metal seed layer, forming a self-assembled monolayer (SAM) on the exposed portions of the metal seed layer to form passivated portions of the metal seed layer, and removing the recessed material fill layer to expose the U-shaped metal seed layer.

In one embodiment, forming the U-shaped metal seed layer comprises forming a material fill layer in the trench, recessing the material fill layer to expose upper portions of the sidewalls of the trench, forming a self-assembled monolayer (SAM) on the exposed upper portions of the sidewalls of the trench, removing the recessed material fill layer, forming the U-shaped metal seed layer at the bottom of the trench, and removing the SAM from the exposed upper portions of the sidewalls of the trench.

In one embodiment, forming the U-shaped metal seed layer comprises forming a metal seed layer at the bottom of the trench and along the sidewalls of the trench to the top of the trench, and removing upper portions of the metal seed layer by angled etching to form the U-shaped metal seed layer.

In one embodiment, forming a metal fill layer on the U-shaped metal seed layer comprises depositing the metal fill layer by atomic layer deposition or chemical vapor deposition.

In an embodiment, a semiconductor structure includes a trench disposed in an inter-layer dielectric (ILD) layer, the trench having sidewalls, a bottom and a top. A conductive liner is disposed at the bottom of the trench and has sidewall portions extending along the sidewalls of the trench to the top of the trench. A passivation layer covers uppermost portions of the sidewall portions of the conductive liner. A material fill layer is disposed on the conductive liner and fills the trench from the bottom of the trench up to a lowermost height of the passivation layer.

In one embodiment, the passivation layer comprises a layer of carbon or a layer of phosphorous.

In one embodiment, the conductive liner is a liner selected from the group consisting of a Co liner, a Ru liner, a TaN liner, a TiN liner, a W liner, and a WN liner.

In one embodiment, the trench has an approximately 12 nanometer opening at the top and has an approximately 10:1 height:width aspect ratio.

In one embodiment, the material fill layer is a layer of metal of a layer of a conductive metal alloy.

In one embodiment, the material fill layer is a metal oxide dielectric layer.

In an embodiment, a method of fabricating a semiconductor structure includes forming a trench in an inter-layer dielectric (ILD) layer, the trench having sidewalls, a bottom and a top, with field regions of the ILD layer exposed adjacent to the top of the trench. The method also includes forming a conductive liner at the bottom of the trench, along the sidewalls of the trench, and on the field regions of the ILD layer. The method also includes forming a passivation layer to cover the conductive liner on the field regions of the ILD layer. The method also includes forming a material fill layer on the conductive liner to fill the trench from the bottom of the trench up to a lowermost height of the passivation layer.

In one embodiment, forming the passivation layer further comprises forming the passivation layer to cover uppermost portions of conductive liner along the sidewalls of the trench.

In one embodiment, forming the passivation layer comprises using a plasma implant process to deposit a carbon layer from CH₄.

In one embodiment, forming the passivation layer comprises using a plasma implant process to deposit a phosphorous layer from PH₃.

In one embodiment, forming the passivation layer comprises using a plasma implant process to deposit a boron layer from B₂H₆ or BF₃.

In one embodiment, forming the material fill layer on the conductive liner comprises depositing the material fill layer by atomic layer deposition or chemical vapor deposition.

What is claimed is:

1. A semiconductor structure comprising:
a trench disposed in an inter-layer dielectric (ILD) layer, the trench having sidewalls, a bottom and a top;
a U-shaped metal seed layer disposed at the bottom of the trench and along the sidewalls of the trench but substantially below the top of the trench; and
a metal fill layer disposed on the U-shaped metal seed layer and filling the trench to the top of the trench, wherein the metal fill layer is in direct contact with dielectric material of the ILD layer along portions of the sidewalls of the trench above the U-shaped metal seed layer.

2. The semiconductor structure of claim 1, wherein the trench is a metal line opening or a via opening in a back end metallization layer.

3. The semiconductor structure of claim 1, wherein the U-shaped metal seed layer has a thickness approximately in the range of 1 nanometer-2 nanometers.

4. The semiconductor structure of claim 1, wherein the U-shaped metal seed layer comprises a material selected from the group consisting of tungsten, tungsten nitride, titanium nitride, ruthenium, and cobalt.

5. The semiconductor structure of claim 1, wherein the U-shaped metal seed layer is disposed along the sidewalls of the trench to a height less than approximately 50% of the height of the trench.

6. The semiconductor structure of claim 5, wherein the U-shaped metal seed layer is disposed along the sidewalls of the trench to a height less than approximately 25% of the height of the trench.

7. The semiconductor structure of claim 1, wherein the metal fill layer is free from a seam or a gap.

8. The semiconductor structure of claim 1, wherein the dielectric material of the ILD layer is a low-k dielectric material.

9. A method of fabricating a semiconductor structure, the method comprising:
forming a trench in an inter-layer dielectric (ILD) layer, the trench having sidewalls, a bottom and a top;
forming a U-shaped metal seed layer at the bottom of the trench and along the sidewalls of the trench but substantially below the top of the trench; and
forming a metal fill layer on the U-shaped metal seed layer to fill the trench to the top of the trench, wherein the metal fill layer is formed selectively on the U-shaped metal seed layer.

10. The method of claim 9, wherein forming the U-shaped metal seed layer comprises:
forming a metal seed layer at the bottom of the trench and along the sidewalls of the trench to the top of the trench;
forming a material fill layer on the metal seed layer;
recessing the material fill layer to expose portions of the metal seed layer;
removing the exposed portions of the metal seed layer to form the U-shaped metal seed layer; and
removing the recessed material fill layer.

11. The method of claim 9, wherein forming the U-shaped metal seed layer comprises:
forming a metal seed layer at the bottom of the trench and along the sidewalls of the trench to the top of the trench;
forming a material fill layer on the metal seed layer;
recessing the material fill layer to expose portions of the metal seed layer;
forming a self-assembled monolayer (SAM) on the exposed portions of the metal seed layer to form passivated portions of the metal seed layer; and
removing the recessed material fill layer to expose the U-shaped metal seed layer.

12. The method of claim 9, wherein forming the U-shaped metal seed layer comprises:
forming a material fill layer in the trench;
recessing the material fill layer to expose upper portions of the sidewalls of the trench;
forming a self-assembled monolayer (SAM) on the exposed upper portions of the sidewalls of the trench;
removing the recessed material fill layer;
forming the U-shaped metal seed layer at the bottom of the trench; and
removing the SAM from the exposed upper portions of the sidewalls of the trench.

13. The method of claim 9, wherein forming the U-shaped metal seed layer comprises:
forming a metal seed layer at the bottom of the trench and along the sidewalls of the trench to the top of the trench; and
removing upper portions of the metal seed layer by angled etching to form the U-shaped metal seed layer.

14. The method of claim 9, wherein forming the metal fill layer on the U-shaped metal seed layer comprises depositing the metal fill layer by atomic layer deposition or chemical vapor deposition.

15. A semiconductor structure comprising:
a trench disposed in an inter-layer dielectric (ILD) layer, the trench having sidewalls, a bottom and a top;
a conductive liner disposed at the bottom of the trench and having sidewall portions extending along the sidewalls of the trench to the top of the trench;
a passivation layer covering uppermost portions of the sidewall portions of the conductive liner; and
a material fill layer disposed on the conductive liner and filling the trench from the bottom of the trench up to a lowermost height of the passivation layer.

16. The semiconductor structure of claim 15, wherein the passivation layer comprises a layer of carbon or a layer of phosphorous.

17. The semiconductor structure of claim 15, wherein the conductive liner is a liner selected from the group consisting of a Co liner, a Ru liner, a TaN liner, a TiN liner, a W liner, and a WN liner.

18. The semiconductor structure of claim 15, wherein the trench has an approximately 12 nanometer opening at the top and has an approximately 10:1 height:width aspect ratio.

19. The semiconductor structure of claim 15, wherein the material fill layer is a layer of metal of a layer of a conductive metal alloy.

20. The semiconductor structure of claim 15, wherein the material fill layer is a metal oxide dielectric layer.

21. A method of fabricating a semiconductor structure, the method comprising:
forming a trench in an inter-layer dielectric (ILD) layer, the trench having sidewalls, a bottom and a top, with field regions of the ILD layer exposed adjacent to the top of the trench;
forming a conductive liner at the bottom of the trench, along the sidewalls of the trench, and on the field regions of the ILD layer;
forming a passivation layer to cover the conductive liner on the field regions of the ILD layer; and
forming a material fill layer on the conductive liner to fill the trench from the bottom of the trench up to a lowermost height of the passivation layer.

22. The method of claim 21, wherein forming the passivation layer further comprises forming the passivation layer to cover uppermost portions of conductive liner along the sidewalls of the trench.

23. The method of claim 21, wherein forming the passivation layer comprises using a plasma implant process to deposit a carbon layer from CH₄.

24. The method of claim 21, wherein forming the passivation layer comprises using a plasma implant process to deposit a phosphorous layer from PH₃.

25. The method of claim 21, wherein forming the passivation layer comprises using a plasma implant process to deposit a boron layer from B₂H₆ or BF₃.
